(19) United States
(12) Patent Application Publication
(10) Pub. No.: US 2013/0335108 A1
(43) Pub. Date: Dec. 19, 2013

(54) DEVICE AND METHOD FOR TESTING ELECTRONIC COMPONENT DEVICES ON A CARRIER OR A SUBSTRATE

(71) Applicant: Multitest elektronische Systeme GmbH, Rosenheim (DE)

(72) Inventors: Andreas Nagy, Munich (DE); Peter Killermann, Ebersberg (DE); Charles Seguna, Bad Aibling (DE); Thomas Kerschl, Edling (DE); Michael Köhler, Rosenheim (DE); Jochen Minwegen, Bad Aibling (DE)

(21) Appl. No.: 13/914,590

(22) Filed: Jun. 10, 2013

(30) Foreign Application Priority Data
Jun. 14, 2012 (EP) 12171997.5

(51) Int. Cl. G01R 1/04

(52) U.S. Cl. CPC G01R 1/0408
USPC 324/750.16; 324/756.02

(57) ABSTRACT

A device for testing electronic component devices on a carrier or a substrate, having a positioning and holding device for the earner or the substrate, a test head and a test socket connected thereto, with which multiple simultaneous electronic component devices on the carrier or the substrate are contactable. At least one additional test socket is connected to the test head.

### CROSS REFERENCE TO RELATED APPLICATION(S)

This application claims priority to and the benefit of the filing date of European Patent Application No. 12171997.5 filed 14 Jun. 2012, the disclosure of which is hereby incorporated herein by reference.

### FIELD OF THE INVENTION

Embodiments of the invention relate to a device and a method for testing electronic component devices on a carrier or a substrate.

### BACKGROUND OF THE INVENTION

Following their production, electronic component devices are usually submitted to specific tests to verify their electrical and/or sensory functions. For this purpose a plurality of electronic component devices are attached to a carrier. This carrier is then transferred to a so-called handler and precisely positioned therein.

If the component devices are to be tested before they are separated into individual devices, that is to say before the substrate on which they were produced has been appropriately sawn, then instead of a carrier with already separated component devices an entire substrate strip is passed to the handler and positioned therein.

The handler has a fixed test head, to which a test socket, also fixed, is connected. For electrical tests the test socket is designed such that all electronic component devices on the carrier or the substrate are contacted and can be tested simultaneously. This is possible even for very small component devices mounted on the carrier at high packing density.

But if, for example, magnetic sensors are to be tested, rotating magnetic fields which do not mutually interact with each other must be generated above the magnetic sensors, and the electrical response of the magnetic sensors must be examined. However, it is not possible to generate the magnetic fields with the same density as the packing density on the carrier or on the substrate. Therefore in this case the test socket only ever contacts part of the component devices and only tests the currently contacted group at the same time.

Only after this step is completed the next group is contacted and tested. It may happen that only every fourth magnetic sensor on the carrier or on the substrate can be tested at once, so that four test steps must be carried out to be able to test all component devices on the carrier or on the substrate.

Opposite to the test socket there is provided a so-called nest, into which the carrier or substrate is inserted in the exact position. The nest is moveable in the x-, y- and z-direction. In this manner the carrier or the substrate can always be positioned such that the electronic component devices to be contacted for the current measurement are positioned opposite to the test socket. The nest together with the carrier or substrate with the component devices to be tested can then be pressed against the test socket with a predetermined force and so an electrically-conductive connection is made between the contacts of the component devices and the test probes of the test socket.

The magnetic sensors already mentioned must be tested not only for their magnetic, but also their electrical functioning, however. This electrical test could be executed for all electronic component devices on the carrier or substrate at the same time. But because the test socket is equipped only with test probes for a group of component devices on the carrier or substrate, the electrical test can also only be carried out in groups. This would result in enormous delays.

In order to avoid these losses a second handler has been previously used. This means that the electronic component devices on the carrier are subjected to magnetic testing in a first handler, and then transferred into a second handler to be subjected to electrical testing. However, this results in increased investment costs due to the second handier and in delays due to the transferral of the substrate.

This issue applies both to electronic component devices on a carrier, and to component devices which are still located on the substrate. This applies equally to both the final test stage for already finished component devices on the substrate, and to an intermediate test stage for component devices which have not yet been finished and onto which other components are mounted following the intermediate test.

### SUMMARY OF THE INVENTION

There may be a need for a device and a method for testing electronic component devices on a carrier or o a substrate such that the delays can be reduced without incurring high investment costs for a second handler.

According to an embodiment of the invention there is provided a device and a method for testing electronic component devices on a carrier or on a substrate having the features of claim 1 and the features of claim 7, respectively.

According to an embodiment of the invention, at least one additional test socket is connected to the test head. It therefore becomes possible within the same handler to carry out a second test, which is either not possible with the test socket for the first test, or could only be carried out with considerable delay. The positioning and holding device for the carrier or the substrate changes the position of the carrier or substrate after the first test, so that electronic component devices on the carrier or the substrate can be contacted with the additional test socket.

Further details and advantages of embodiments of the invention are obtained from the dependent claims.

In an advantageous exemplary embodiment of the invention, the other test socket is designed in such a way that a single electronic component device on the carrier or substrate can be contacted therewith. This results in enormous advantage if an electronic component device shows a test result in a first test which apparently indicates that the tested component device is not in working order, but also leaves open the possibility that during the test it was merely the contacting between component device and test socket which was not quite correct. Such problems can be caused by dust, for example.

The component device can now be tested with the additional test socket a second time, but without the component devices already evaluated as good having to be contacted with test probes again. This repeated contacting is to be avoided in any events, since each contacting is carried out with large forces and during a repeated contact damage could occur to a component device which has already been passed as good. The components evaluated as faulty have therefore been previously disposed of as waste, even if the test was failed only due to a contact error.

In another exemplary embodiment the additional test socket is designed in such a way that a plurality of electronic component devices on the carrier or substrate can be contacted simultaneously. This exemplary embodiment can be applied, for example, when in an initial test only a group of component devices can be tested at the same time. E.g., the component devices on the carrier or substrate must be subjected to initial test in four steps. In the second test with the additional socket, the test may be carried out in two steps, for example. Also, this embodiment results in a time saving as compared to the use of a handler in which the second test would have to be carried out with the test socket for the first test in four steps.

If, for example, magnetic sensors are to be investigated for their sensitivity to a magnetic field and for their electronic properties, another exemplary embodiment of the invention is suitable. Since for the magnetic test it is only possible to use a test socket with a lower packing density of magnetic field generators than the packing density of component devices on the carrier or substrate, this test must be carried out in a plurality of steps. In contrast, in the electronic testing the other test socket can be as densely packed with groups of test probes for the individual component devices as there are component devices present on the carrier or substrate. Therefore only a part of the electronic component devices on the carrier or the substrate can be simultaneously contacted with the test socket for the magnetic test, while all electronic component devices on the carrier or substrate can be contacted with the other test socket simultaneously.

In order to save time, it is necessary to avoid having to transfer the carrier or the substrate with the test socket into a second positioning and holding fixture after the first test. The existing positioning and holding fixture should therefore be designed such that the carrier or the substrate is positioned under both the test socket and the additional test socket for contacting.

In any case it should be avoided that electronic component devices are contacted more often than absolutely necessary, since the contacts must be made under high pressure and the risk of damage to the component devices cannot be ruled out. In the second test with the additional test socket, care should therefore be taken to ensure that the only component devices that are contacted again are those which actually have to be subjected to the second test. This also means that electronic component devices are not to be contacted by the test socket a second time for the first test. The two test socket and the positioning and holding fixture must therefore be appropriately matched to each another. Accordingly, the two test sockets are so arranged that each electronic component device on the carrier or the substrate can be contacted by one of the test sockets without any other component device being contacted by the other test socket.

In the method according to an embodiment of the invention, electronic component devices on the carrier or the substrate are first of all contacted by the test socket, while at least one electronic component device on the carrier or substrate is subsequently contacted by a further test socket and the measured data are passed to the same test head. By means of this sequence of method steps it is ensured that the first test is completed, and the second test with the additional test socket can even be made to depend on the result of the first test. It is also possible in this way to carry out the second test in the same handler very quickly.

As already explained above, in the testing of magnetic sensors, for example, it is not possible to contact all component devices on the carrier or substrate with the test socket simultaneously, since the generation of the magnetic field needed for the test requires more space than the electrical contacting of the component devices. In order to be able to test all electronic component devices on the carrier or substrate, the electronic component devices on the carrier or substrate must be contacted by the test socket in a series of individual steps. To this end, all electronic component devices on the carrier or substrate are divided into groups and the electronic component devices of a group are each contacted by the test socket at the same time.

In particular when testing component devices in which a first test must be carried out in a series of steps, a great deal of time can be saved if a second necessary test can be performed not with the same test socket, again in a series of individual test steps, but with an additional test socket in a single test step. For this purpose, all electronic component devices on the carrier or substrate are contacted by the further test socket simultaneously.

### BRIEF DESCRIPTION OF DRAWINGS

Further details and advantages of embodiments of the invention result from the description of an exemplary embodiment, which will be explained in detail based on the drawing.

Shown are:

FIG. 1 is a schematic view of a handler according to an embodiment of the invention,

FIG. 2 is a schematic illustration of a test of component devices with a first array test socket in the handler according to FIG. 1,

FIG. 3 is a test with a second array test socket,

FIG. 4 is a view of an additional handler according to an embodiment of the invention

FIG. 5 is an illustration of a test of component devices with a first array test socket in the handler according to FIG. 5, and

FIG. 6 is a test with a second single-test socket.

### DETAILED DESCRIPTION OF THE INVENTION

The handler according to FIG. 1 comprises a compression die 5, which can be moved evenly up and down by means of the threaded rods 8. On the compression die the nest 6 is provided, which contains the holder for the substrate 7, and together with an XY displacement device not shown here, forms the positioning and holding device for the substrate 7.

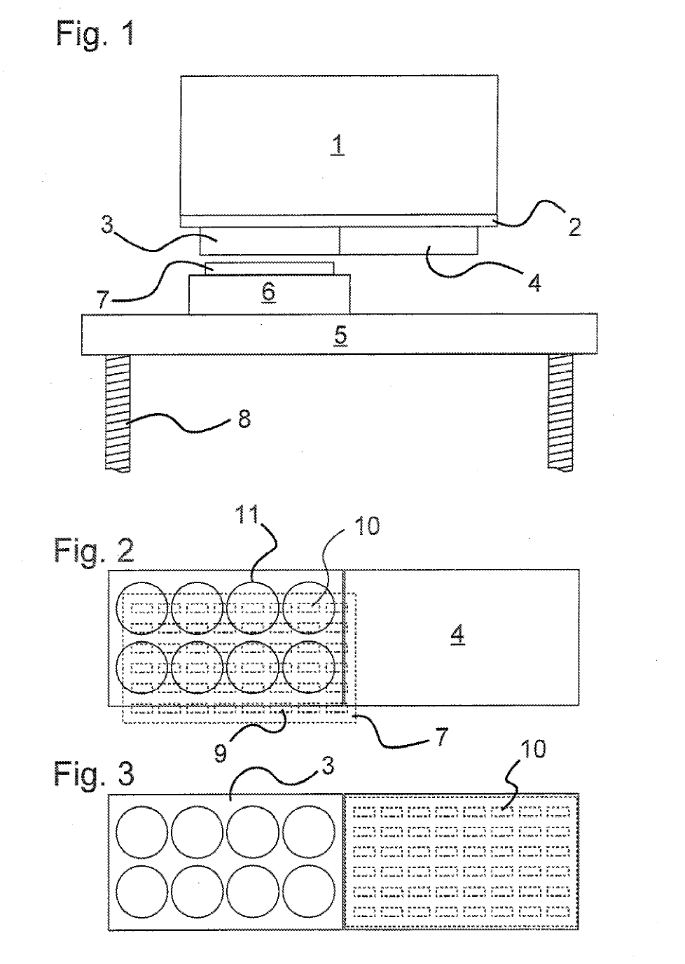

By using the nest 6, the carrier can be positioned below the first array test socket 3 or the second array test socket 4 with high precision. The component devices 9 and 10 shown in FIGS. 2 and 3 are attached to the carrier.

For example, in the drawing the component devices are arranged on a carrier. The carrier can be implemented as a damping carrier as is described, for example, in WO 2009/100910 A1. The nest 6 however can also be fitted with a holder for a substrate strip, if component devices which have not yet been separated are to be tested.

The test head 1 is mounted above the compression die 5 and the nest 6 as a fixed, immovable module. The connection between the test head 1 and the test sockets 3 and 4 is created by the loadboard 2.

To test the component devices the compression die 5 is moved upwards and the contacts of the component devices are pressed with a large force against the test probes of the test sockets 3 and 4. If component devices are to be tested on a substrate, test probes are usually in contact with contact pads on the substrate, which are arranged facing the component devices.

In the exemplary embodiment shown in FIGS. 1 to 3, magnetic sensors are to be tested on a damping carrier. To do this, both the sensitivity with respect to a magnetic field, as well as the electronic properties are tested. In the first test socket 3 therefore, eight magnetic field generators 11 are arranged, each generating a rotating magnetic field.

As can be taken from FIG. 2, the magnetic field generators 11 require a relatively large amount of space, so that not all component devices 9 held on the carrier 7 can be tested at the same time. In the position shown in FIG. 2, only the component devices 10 seen in the centre of the the respective magnetic field generators 11 can be tested.

For this purpose, the compression die is moved upwards, so that the contacts of this group of eight component devices 10 are pressed against the test probes of the first test socket 3. The magnetic field generators 11 are then set into operation and the resulting signals relayed to the test head 1.

If the test step for this group of component devices 9 is completed, the compression the 5 is moved down again and the carrier 7 repositioned on the nest 6, such that eight other component devices can be tested. In order to keep the positioning time as short as possible, for the next test in the sequence it is useful to select a group of component devices which are located directly next to those already tested. Thus for example, for the second test step the nest 6 with the carrier 7 can be moved far enough to the left so that in each case the component devices to the right of those already tested come to rest in the middle of the magnetic field generators 11. For the third test step the carrier 7 is then moved upwards and for the fourth step, moved to the right.

In the example shown here, six test steps are necessary before all component devices 9 on the carrier 7 are tested. Thereafter it only remains to carry out the electronic test with the second test socket 4 in one step. For this purpose the nest 6 with the carrier 7 is positioned under the second test socket 4. Since the test probes in the test socket can be packed as closely as the contacts of the component devices 9 on the carrier, the electronic test is possible in a single step.

Compared with known handlers with only one test socket, this measure can save a great deal of time. In these known handlers the electronic testing had to be carried out with the first probe as well. For this task, as for the magnetic test, 6 individual test steps were also necessary. Assuming that approximately 10 sec are required for the electronic test, then for this test with the first test head a time interval of 60 sec is required, because of the 48 component devices on the carrier 7, only 8 component devices can ever be measured at the same time, and therefore six measurement procedures are necessary.

With the second test socket 4 according to an embodiment of the invention, however, all component devices can be tested at the same time in 10 sec. Calculating in a further 2 sec for the repositioning under the second test socket 4, a time saving of about 48 sec is obtained for testing all component devices 9 arranged on the carrier 7.

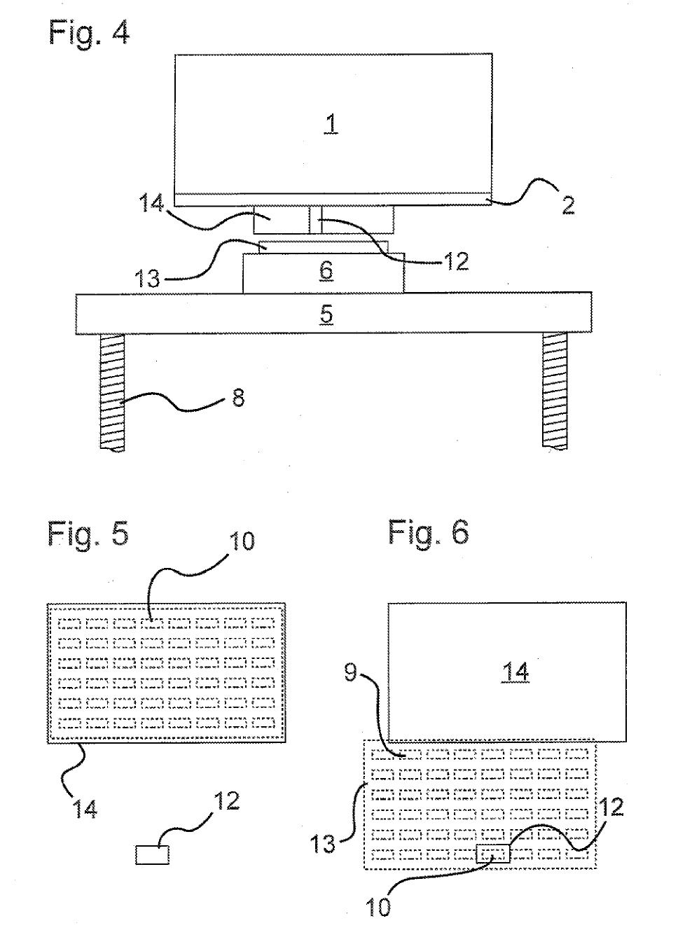

A further application of an embodiment of the invention is shown in the exemplary embodiment according to FIGS. 4 to 6. Here a second test socket is implemented as a single-test socket 12. Otherwise, equivalent parts are also labelled with the same reference numeral as in FIGS. 1 to 3.

In this embodiment a test socket 14 is provided as the first test socket for the electronic test, which socket corresponds to the second test socket 4 of the exemplary embodiment according to the FIGS. 1 to 3. The second test socket 12 by contrast is a test socket which only contacts a single component device.

In the electronic testing of electronic component devices, it occurs again and again, that a component device will be classified as faulty, even though all necessary functions are satisfactorily met. This often occurs as a result of contacting problems which can be caused by dust particles, for example. Hitherto, such component devices were rejected as waste.

A repetition of the electronic test would have meant that all component devices which had passed would also have had to be contacted for a second time, which as already described above, may result in damage to the component devices that have passed the test.

If the component devices are arranged not on a substrate but on a carrier, such as a damping carrier, the possibility would also exist to separate failed component devices, to place them on another damping carrier and then to subject only the failed component devices to a second test. In this case, however, a packaging process corresponding to the production batches would be extremely complicated, because the twice-tested component devices would have to be merged with the first-tested ones.

In both cases, disadvantages would result which may not be in proportion to any costs that might be saved. Therefore, all component devices which have failed the first test have therefore been sorted out and disposed of.

With the handler according to FIG. 4, such losses can avoided in a simple manner and with low cost. The substrate 13 with the component devices 9 is placed and held on the nest such that the component devices 9 are located on the underside of the substrate 13. In contrast, the contact surfaces are arranged on the top of the substrate 13. Of course, the nest 6 in this exemplary embodiment could also be designed in such a way that a carrier populated with electronic component devices can be held. In both cases, the advantages obtained by the additional single-test socket 12 are the same.

In order to test the component devices 9 the nest 6 is now positioned and held under the array test socket 14 for the electrical test. When powering up the compression die 5, the contact surfaces of all component devices 9 are brought into contact with the test probes of the test socket 14 simultaneously. All component devices 10 can be tested in parallel in this manner. If no faults are detected during this test, this test is completed and the tested component devices can be further processed.

If, however, a fault is detected in a component device, the compression die 5 is moved downwards and the nest 6 is positioned such that the component device 10 tested as faulty is located underneath the single test socket 12. The compression die 5 is moved back up again and the contact surfaces of the substrate 13 assigned to this component device 10 are pressed onto the test probes of the single-test socket 12.

If the result of this anew test also turns out to be negative, the component device is classified as to be faulty and is disposed of after separation. In the other case, all component devices 9 arranged on the substrate are further processed.

If in a series of tested substrates 13 a fault is always found on the same component device in the first test, but on the second test with the single-test socket 12 the component device is found as to be good, it can be assumed that the array test socket 14 for the first test is faulty. In this case, the test probes involved require cleaning or replacement.

An additional single-test socket 12 is therefore always useful when more than one component device is tested at the same time in the test being carried out. It does not matter whether the whole component device array, a row or column thereof, or another selected group of component devices is being tested simultaneously. Due to the additional single-test socket 12, a re-contacting of the component devices which have passed the test can be avoided, so that as a result only the component device in which an error has been detected in the first test needs to be contacted again. The single-test socket 12 however is also used for quickly detecting faults and defects in the array test socket 14.

What is claimed is:

1. A device for testing electronic component devices on a carrier or a substrate, comprising:
a positioning and holding device for the carrier or the substrate; and
a test head and a test socket connected thereto, with which a plurality of electronic component devices on the carrier or the substrate can be contacted simultaneously, wherein at least one additional test socket is connected to the test head.

2. The device according to claim 1, wherein the additional test socket is configured in such a manner that a single electronic component device on the carrier or the substrate can be contacted therewith.

3. The device according to claim 1, wherein the additional test socket is configured such that a plurality of electronic component devices on the carrier or the substrate can be contacted simultaneously.

4. The device according to claim 1, wherein a part of the electronic component devices on the carrier or the substrate can be contacted with the test socket and all electronic component devices on the carrier or substrate can be contacted with the additional test socket simultaneously.

5. The device according to claim 1, wherein the positioning and holding device is designed such that the carrier or the substrate can be positioned under both the test socket and under the additional test socket to provide contacting.

6. The device according to claim 1, wherein the two test sockets are arranged such that each electronic component device on the carrier or the substrate can be contacted by one of the test sockets, without any other component device being contacted by the other test socket.

7. A method for testing electronic component devices on a carrier or a substrate, in which a plurality of electronic component devices on the carrier or the substrate are contacted simultaneously by a test socket and measured data are forwarded to a test head, comprising the steps of:
first all electronic component devices on the carrier or the substrate are contacted by the test socket; and
then at least one electronic component device on the carrier or the substrate is contacted by an additional test socket and measurement data are forwarded to the same test head.

8. The method according to claim 7, wherein the electronic component devices on the carrier or the substrate are contacted by the test socket in a plurality of individual steps, by all electronic component devices on the carrier or the substrate being divided into groups and the electronic component devices of one group being contacted by the test socket at the same time.

9. The method according to claim 7, wherein all electronic component devices on the carrier or the substrate are contacted by the additional test socket simultaneously.
